(19) United States
(12) Patent Application Publication
(10) Pub. No.: US 2014/0307997 A1
(43) Pub. Date: Oct. 16, 2014

(54) HYBRID INTEGRATION OF GROUP III-V SEMICONDUCTOR DEVICES ON SILICON

(71) Applicants: Hanan Bar, Mevaseret Zion (IL); John Heck, Berkeley, CA (US); Avi Feshali, Los Angeles, CA (US); Ran Feldesh, Gan Yavne (IL)

(72) Inventors: Hanan Bar, Mevaseret Zion (IL); John Heck, Berkeley, CA (US); Avi Feshali, Los Angeles, CA (US); Ran Feldesh, Gan Yavne (IL)

(21) Appl. No.: 13/976,913

(22) PCT Filed: Dec. 20, 2011
(86) PCT No.: PCT/US11/66255

§ 371 Date: Jan. 8, 2014

(51) Int. Cl. G02B 6/122; H01L 21/8252; H01L 29/205; G02B 6/13

(52) U.S. Cl. CPC G02B 6/1225; G02B 6/13; H01L 21/8252; H01L 29/205; G02B 2006/12061
USPC 385/14; 438/24; 438/107; 257/201

(57) ABSTRACT

Photonic passivation layers, III-V semiconductor die with offcut edges, and NiGe contact metallization for silicon-based photonic integrated circuits (PICs). In embodiments, a non-sacrificial passivation layer is formed on a silicon photonic element, such as a waveguide for protection of the waveguide surfaces. In embodiments, a III-V semiconductor film is transferred from a III-V growth substrate that is singulated along streets that are misaligned from cleave planes to avoid crystallographic etch artifacts in a layer transfer process. In embodiments, a NiGe contact metallization is employed for both p-type and n-type contacts on a device formed in the transferred III-V semiconductor layer to provide low specific contact resistance and compatibility with MOS processes.

### TECHNICAL FIELD

Embodiments of the invention are generally related to semiconductor devices, and more particularly to photonic integrated circuits (PICs) and fabrication thereof.

### BACKGROUND

Monolithically integrated photonic circuits are useful as optical data links in applications such as, but not limited to, high performance computing (HPC), optical memory extension (OME), and inter-device interconnects. For mobile computing platforms too, a PIC is a useful means of I/O to rapidly update or sync a mobile device with a host device and/or cloud service where a wireless or electrical link has insufficient bandwidth. Such optical links utilize an optical I/O interface in that includes an optical transmitter and an optical receiver.

Silicon-based PICs are a particularly advantageous form of PICs because they are compatible with many of the fabrication techniques that have been developed over decades, for example to implement electrical integrated circuits (EICs) using complementary metal oxide semiconductor (CMOS) technology. Silicon-based PICs therefore offer cost advantages of mature manufacturing technology and also off the advantage of being monolithically integrated with EICs.

During the fabrication of silicon photonic devices of a PIC however, the silicon may be attacked chemically. Resulting small changes to the dimensions of the waveguides, gratings, and other photonic features can be extremely detrimental to the performance of the devices by changing the characteristic frequency or increasing optical loss of the devices. Conventionally, many silicon surfaces of a photonic structure may be covered by silicon dioxide (SiO₂), silicon nitride (Si₃N₄), or left uncovered. While silicon dioxide advantageously serves a high-index-contrast cladding function, the fabrication process frequently results in removal of silicon dioxide claddings (e.g., during hydrofluoric (HF)-based wet cleans, etc.). Silicon nitride is therefore often used because it has a high HF resistance. However, although silicon nitride does not have a high index-contrast, it cannot be removed with high selectivity to the underlying silicon and so, in many cases the silicon is left unprotected, and subject to subsequent chemical attack. Techniques and structures for protecting photonic elements of a silicon-based PIC would therefore be advantageous.

While silicon-based PICs have advantages, group III-V compound semiconductor materials are advantageous in many photonic devices, particularly active photonic devices which offer some form of optical gain like lasers. As such, hybridizing a silicon-based PIC through integration with devices including a III-V semiconductor material is desirable. One avenue for hybridizing is bonding of a III-V semiconductor material to a surface of the silicon-based PIC and then removing the group III-V semiconductor growth substrate (i.e., a transferred layer process). Typically, such removal processes entail an initial bulk etch and final selective chemical etching process. Many chemical etching processes however are crystallographic resulting in the transferred group III-V semiconductor material having a crystallographic rim many microns high as an artifact of the transfer process. Such non-planarity is detrimental to subsequent fabrication process (e.g., spin coating, photolithographic imaging focus, etc.). Techniques and structures which reduce or eliminate such sources of non-planarity would therefore be advantageous.

To retain the advantage of integrating a silicon-based PIC with silicon-based EICs, devices formed in any III-V compound semiconductor material disposed on the PIC substrate should also be compatible with silicon-based EICs. One potential incompatibility arises in the contact metallization of the III-V semiconductor device. Conventionally, many contact metals developed in the context of III-V devices contain gold (Au) which is a known contaminant highly detrimental to silicon-based EICs (particularly MOS technologies). Many other contact metals are difficult to pattern, relying on low-yielding techniques, such as lift-off. Contact metallization techniques and structures which offer good parametrics (e.g., low specific contact resistance, R_{c}), that are compatible with silicon-based EICs, and highly manufacturable would therefore be advantageous.

### BRIEF DESCRIPTION OF THE DRAWINGS

Embodiments of the present invention are illustrated by way of example, and not by way of limitation, and can be more fully understood with reference to the following detailed description when considered in connection with the figures in which:

FIG. 1 is a flow diagram illustrating a method of forming a photonic passivation layer, in accordance with an embodiment;

FIGS. 2A, 2B, 2C, 2D, and 2E are side views of a cross-section through a silicon PIC as a photonic passivation layer is formed, in accordance with an embodiment;

FIG. 3 is a flow diagram illustrating a method of forming a photonic passivation layer, in accordance with an embodiment;

FIGS. 4A, 4B, 4C, and 4D are side views of a cross-section through a PIC as a photonic passivation layer is formed, in accordance with an embodiment;

FIG. 5 is a graph showing an etching behavior of a photonic passivation layer, in accordance with an embodiment;

FIG. 6 is a flow diagram illustrating a method of forming a hybrid semiconductor device including a group III-V semiconductor layer disposed on a silicon-based substrate, in accordance with an embodiment;

FIG. 7A is a plan view of a group III-V semiconductor substrate singulated into die, in accordance with an embodiment;

FIGS. 7B and 7C are side views through a cross-section of a hybrid semiconductor device including a group III-V semiconductor material layer transferred from a die illustrated in FIG. 7A to be disposed on a silicon-based substrate;

FIG. 8 is a flow diagram illustrating a method of forming contact metallization on a group III-V semiconductor device, in accordance with an embodiment;

FIGS. 9A, 9B, 9C, 9D, 9E, 9F, 9G are side views of a cross-section as contact metallization is formed on a device formed in a group III-V semiconductor material layer disposed on a silicon-based substrate, in accordance with an embodiment;

FIG. 10 is a schematic diagram of a mobile device including an optical transmitter, in accordance with embodiments of the present invention; and

FIG. 11, is a function block diagram of the mobile device illustrated in FIG. 10, in accordance with an embodiment of the present invention.

### DETAILED DESCRIPTION

In the following description, numerous details are set forth, however, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” means that a particular feature, structure, function, or characteristic described in connection with the embodiment is included in at least one embodiment of the invention. Thus, the appearances of the phrase “in an embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the two embodiments are not mutually exclusive.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” my be used to indicated that two or more elements are in either direct or indirect (with other intervening elements between them) physical, optical, or electrical contact with each other, and/or that the two or more elements co-operate or interact with each other (e.g., as in a cause an effect relationship).

The terms “over,” “under,” “between,” and “on” as used herein refer to a relative position of one component or material layer with respect to other components or layers where such physical relationships are noteworthy. For example in the context of material layers, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similar distinctions are to be made in the context of component assemblies.

Described herein are devices and structures including one or more of a photonic passivation layer (PPL), silicon/III-V hybrid photonic devices, and contact metallization structures. Also described herein are techniques for forming and integrating such devices and structures. The various devices, structures, and techniques are described herein primarily in the context of a silicon-based PIC to emphasize the synergistic embodiments of the present invention. However, as one of ordinary skill in the art will appreciate, many of the embodiments described herein may be readily implemented outside of the exemplary silicon-based PIC explicitly described herein.

In embodiments, a photonic element of a PIC includes a PPL comprising a nitrogen-doped, or “nitride” silicon oxide. Generally, the PPL is to protect surfaces of the photonic element against wet etchants such as phosphoric acid, ammoniac solutions, as well as dry plasma etch processes performed subsequent to the formation of the photonic element. Such attack is a problem particularly for a silicon photonic device where a surface consisting essentially of silicon can be pitted during subsequent processing. For example, in an exemplary hybrid laser process wherein a group III-V semiconductor material is bonded to a surface of a silicon waveguide, chemicals may attack the silicon beneath the III-V material, causing pitting in the waveguides. In embodiments, the PPL is non-sacrificial (i.e., permanent) and so is retained in a fully functional PIC. In contrast to a silicon nitride layer, the nitrided silicon oxide has more oxygen atoms and is significantly thinner than what a convention CVD nitride deposition process can achieve. Therefore, in addition to the PPL embodiments described herein being highly resistive to etchants, certain PPL embodiments may induce only undetectable/insignificant degradation (e.g. optical loss) in the photonic elements.

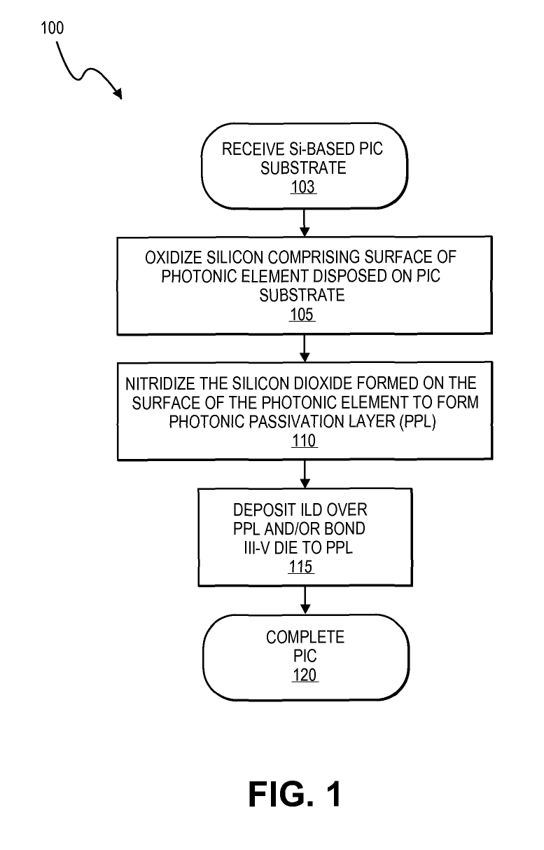

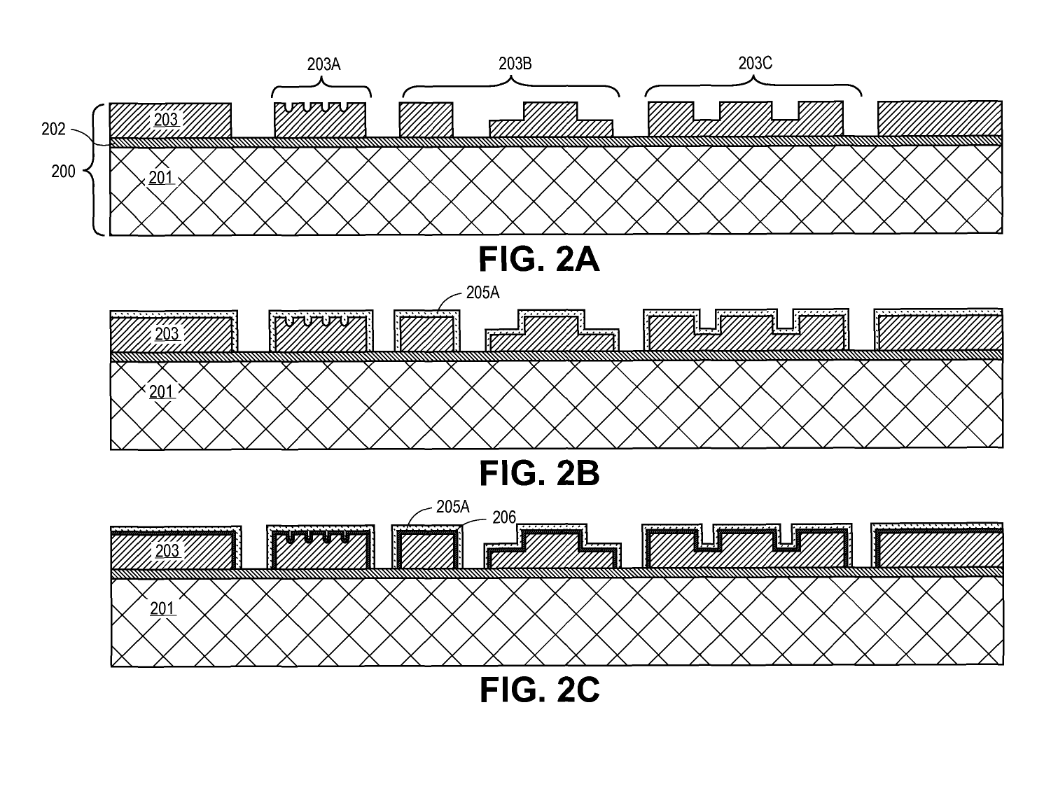

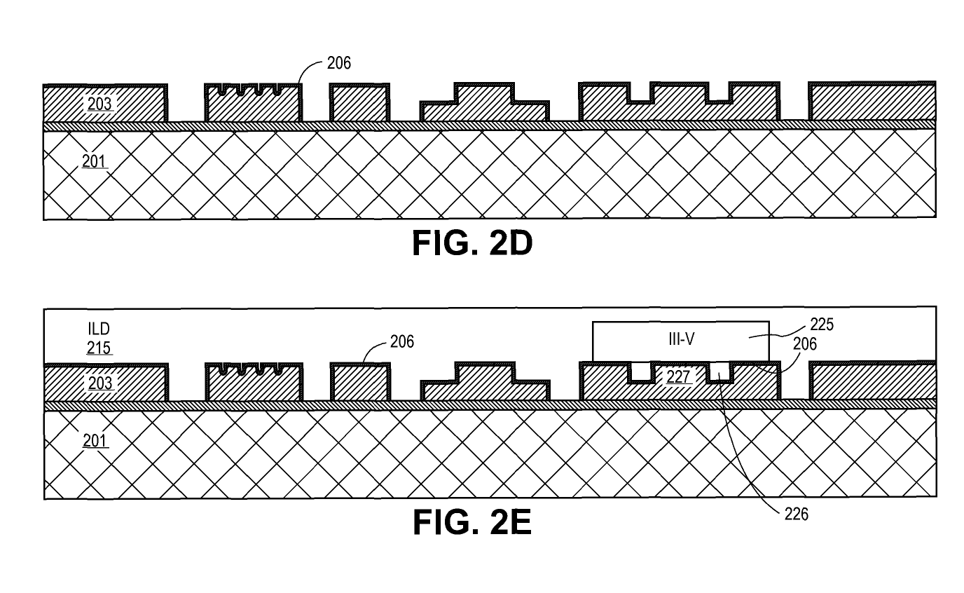

FIG. 1 is a flow diagram illustrating a method 100 of forming a PPL, in accordance with an embodiment. Method 100 begins with receipt of a silicon PIC at operation 103. As employed herein, a silicon PIC is a PIC that includes one or more photonic elements (passive or active) comprising silicon, some of which consist essentially of silicon (i.e., a silicon photonic element) while others may comprise an alloy of silicon (e.g., SiC, SiGe, etc.). In the exemplary embodiment, a silicon photonic element is of a single crystal, though polycrystalline (silicon) and amorphous (silicon) embodiments are also possible. FIG. 2A illustrates a side view of a cross-section through a silicon PIC including a semiconductor-on-insulator (SOI) substrate 200. The SOI substrate 200 is includes a bulk substrate 201 (monocrystalline), a buried dielectric layer 202 (SiO₂), and a device layer 203 (also monocrystalline in the exemplary embodiment). As shown, various photonic elements including a grating 203A, waveguides 203B, and a hybrid laser 203C are fabricated from the device layer 203. As such, the device layer 203 is silicon in the exemplary embodiment as is the bulk substrate 201. Any other known photonic element may also be present on the silicon PIC, such as, but not limited to, tapers and multimode interference (MMI) couplers.

Returning to FIG. 1, at operation 105, at least one surface of a photonic element is oxidized to form a silicon-comprising oxide (i.e., the silicon is sourced from the photonic element). In the exemplary embodiment illustrated in FIG. 2B where the device layer 203 consists essentially of silicon, a SiO₂ layer 205A is formed on surfaces of the photonic elements 203A, 203B, and 203C exposed to the oxidation process performed at operation 105. In embodiments of the present invention, the oxidation process is other than a native oxidation (i.e., that which forms on silicon at STP conditions). Generally, the SiO₂ layer 205A is to be of a well-controlled thickness and quality with most any tunnel oxide process conventional to non-volatile random access memory (NVRAM) technologies (e.g., flash memory) being an excellent candidate for formation of a PPL with respect to both thickness and quality uniformity and control. In embodiments, the SiO₂ layer 205 is formed to a thickness approximately in the range of 1-10 nanometers (nm). Greater thicknesses are also possible, though as described elsewhere herein, as only a portion of the SiO₂ layer 205 is converted into a PPL, greater thicknesses offer little advantage once the thickness is sufficient to achieve adequate uniformity and repeatability of film quality and thickness.

While many techniques exist for forming tunnel oxide, in embodiments herein, in exemplary embodiments operation 105 entails one or more of a thermal oxidation or radical oxidation process. As each of these techniques are readily obtainable by the interested reader in the context of tunnel oxide growth, it is sufficient to note here that a thermal oxidation process generally employs a dry O₂ source at a temperature in the range of 900-1000° C. while a radical oxidation process typically uses oxygen (O₂) and hydrogen (H₂) gas at a temperature approximately in the range of 1000-1100° C. and may further employ in situ steam generation (ISSG) techniques. In an alternate embodiment, operation 105 entails any plasma oxidation process known in the art, though uniformity and quality may be somewhat less than for furnace embodiments.

Method 100 then proceeds to operation 110 where the silicon-comprising oxide (e.g., SiO₂) formed at operation 105 is nitrided by incorporating nitrogen atoms to form a layer of nitrogen-rich silicon oxide (SiOₓN_{y}) as the PPL. Depending on the technique employed at operation 110, the nitrogen concentration profile may vary. In the exemplary embodiment illustrated by FIG. 2C, nitrogen concentration increases toward the surface of the photonic elements 203A, 203B, 203C so that a thickness of a nitrogen-rich silicon oxide PPL 206 less than the thickness of the SiO₂ layer 205A is formed at the interface of the silicon surface. In the exemplary embodiment, where operation 105 includes a thermal anneal of the SiO₂ layer 205A (e.g., performed in the presence of a nitrogen-containing source gas, such as NO, at 850-1100° C.), nitrogen diffuses through the SiO₂ layer 205A as the SiO₂ layer 205A anneals into annealed SiO₂ layer 205B to create a nitrogen-rich silicon oxide PPL 206 between approximately 5 and 15 Å in thickness.

Advantageously, both the oxidation operation 105 and the nitridation operation 110 are highly conformal processes in the exemplary embodiment, so that both sidewalls and top surfaces of a photonic structure are protected by a layer having of substantially the same controllable composition and thickness. With this technique, the nitrogen content with the PPL 206 may be tailored to be anywhere from 10¹² to 10¹⁶ atoms/cm³. In further embodiments, additional sub-surface nitrogen may be added through an implantation process, if desired. The highly conformal and extremely thin film will have little adverse effect on the photonic properties of the photonic elements.

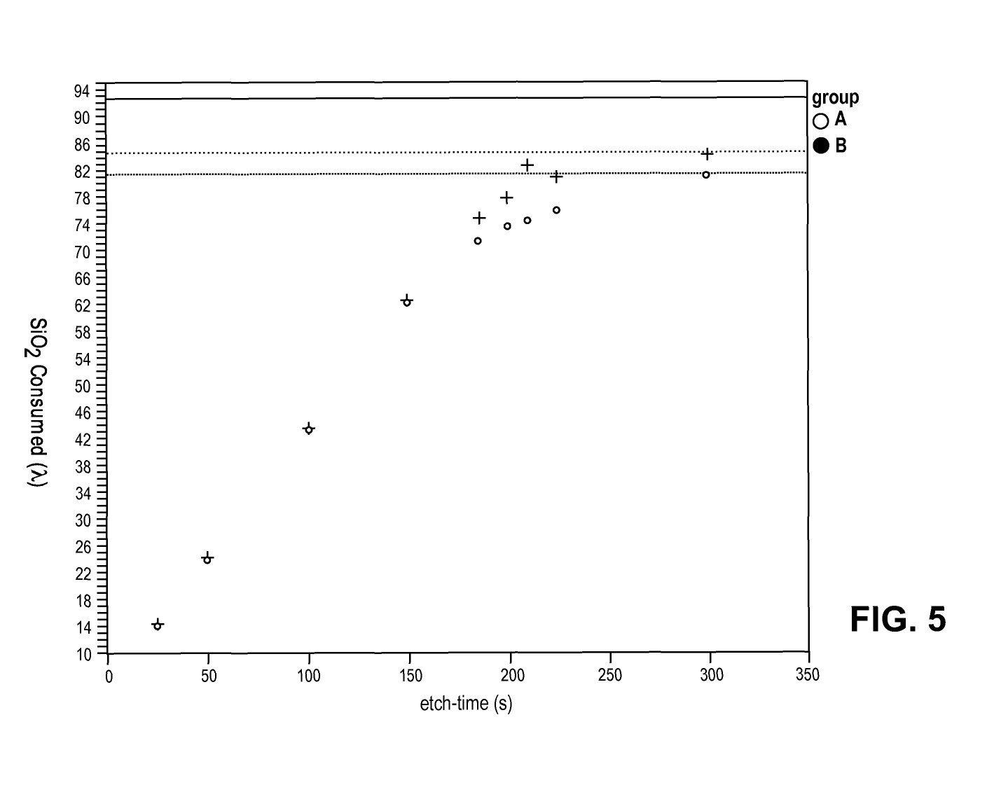

In embodiments, as illustrated by FIG. 2D, processing of a PIC may entail exposure to one or more etchants which remove the annealed SiO₂ layer 205B. The PPL 206 however, being nitrogen-rich and free from pinholes, is impervious to etchants, thereby protecting the underlying photonic element surfaces (e.g., silicon surfaces). FIG. 5 is a graph showing an etching behavior of a photonic passivation layer, in accordance with an embodiment. The amount of annealed SiO₂ layer 205B consumed is shown on the y axis in Å as a function of etch time (seconds) in Trimix (500:1 buffered oxide etch). Notably, for two different embodiments of the oxidation and nitridation operations 105, 110, that result in a 93 Å total thickness over the underlying silicon surface, the etch plateaus at about 82-84 Å, indicating a remaining robust nitrided film of about 10 Å. This film has also been shown to withstand 50:1 HF.

Returning to FIG. 1, the PPL 206, being non-sacrificial in the exemplary embodiment, is buried under an interlayer dielectric material (ILD) at operation 115. Exemplary ILD materials include, but are not limited to silicon dioxide, and carbon-doped silicon dioxide. In further embodiments, transferred semiconductor layer is bonded to the PIC through the PPL 206. As further illustrated in FIG. 2E, a die including a group III-V semiconductor material 225 is bonded directly in contact with the PPL 206 as part of a transferred substrate process to form a top of the hybrid laser 203C. Known bonding techniques, for example employing a plasma activation process, have been found capable of bonding to the PPL 206. As such, the rib waveguide 227 defined by the trenches 226 can remain protected by the PPL 206 to prevent pitting of the silicon beneath the III-V semiconductor material 225 with the hybrid laser 203C remaining functional (e.g. evanescent). The ILD 215 is then deposited over both the group III-V semiconductor material 225 and the PPL 206. The method 100 (FIG. 1) then proceeds with completion of the microelectronic device at operation 120, following conventional techniques, and/or incorporating one or more embodiments described elsewhere herein.

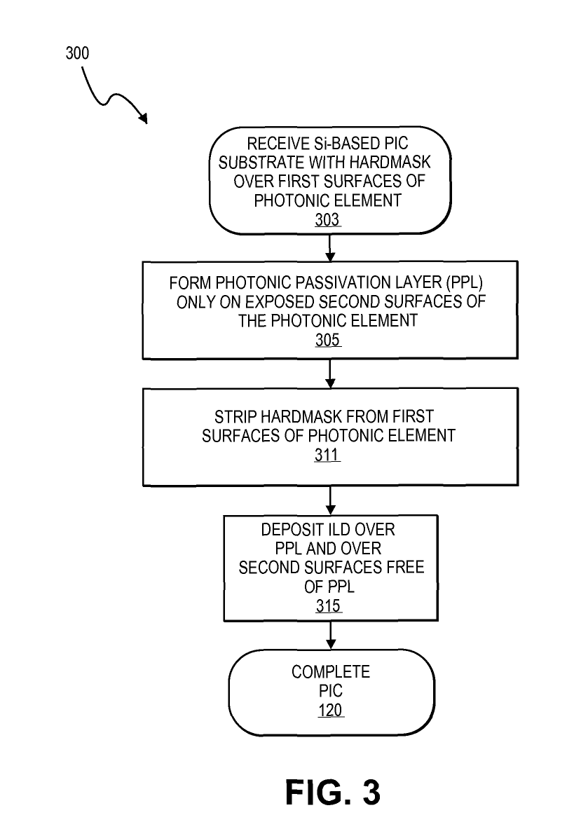

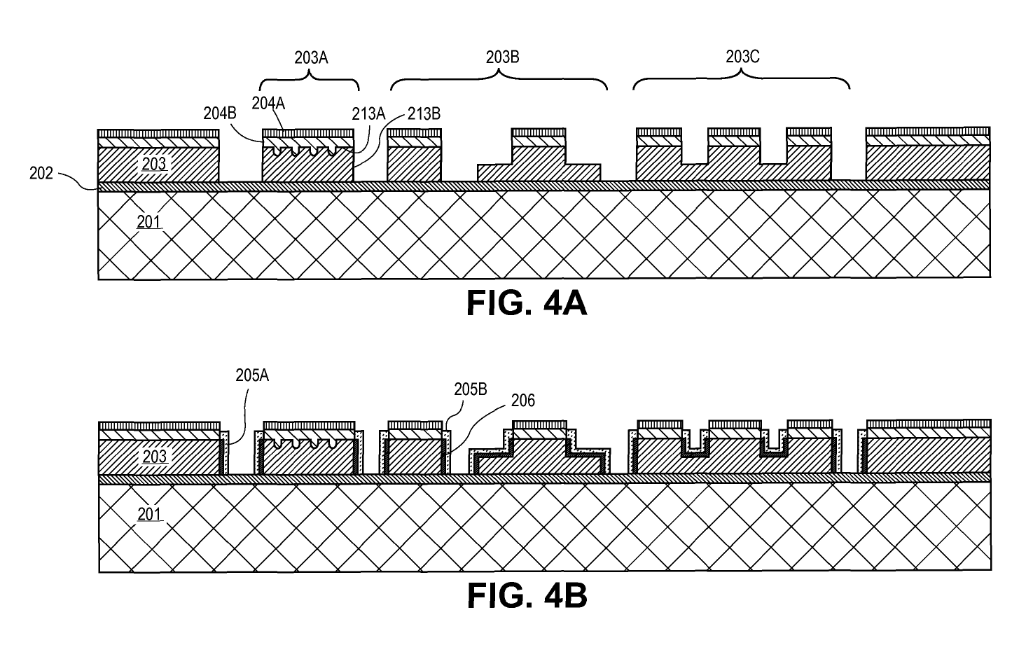

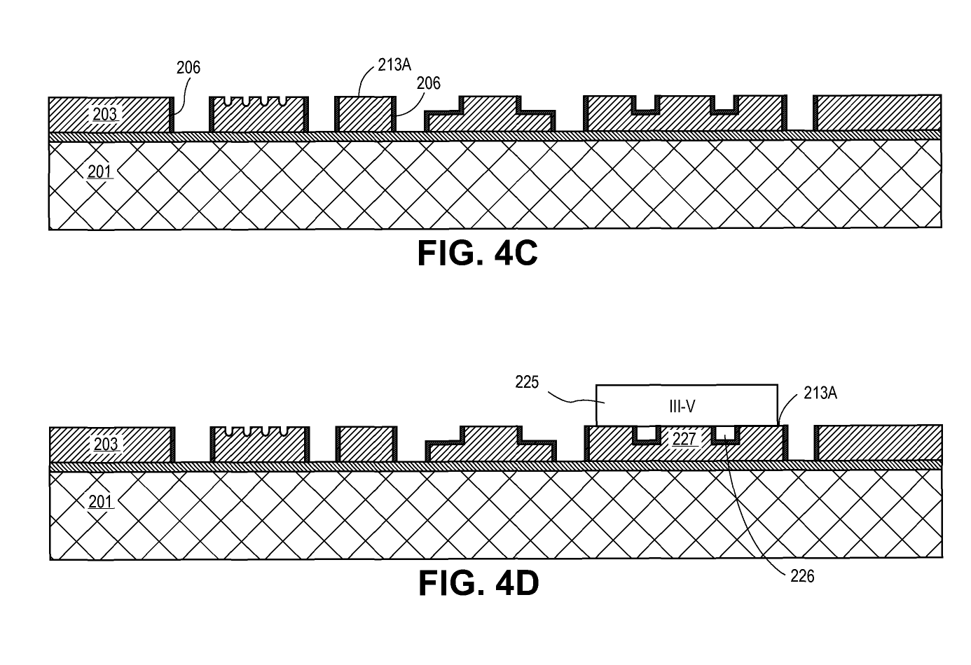

In an embodiment, the PPL 206 is selectively disposed on surface other than top surfaces of a photonic element. FIG. 3 is a flow diagram illustrating a method 300 of selectively forming a photonic passivation layer in accordance with such an embodiment. Method 300 beings at operation 303, with receipt of a PIC including silicon photonic elements, substantially as previously described for operation 103 (FIG. 1) with the exception that a hardmask is disposed on top surfaces of the photonic elements. FIG. 4A is a side view of a cross-section through a PIC with a hardmask including layers 204A and 204B that were utilized to form the photonic devices (e.g., an etch mask of the device layer 203). In the exemplary embodiment, a SiO₂ mask layer 213A is disposed on the top surface 213A of a photonic element and a Si₃N₄ mask layer 213B is disposed on the SiO₂ mask layer 213A.

Referring again to FIG. 3, at operation 305 a PPL is formed only on exposed second surfaces of the of the photonic element (i.e., those surfaces not protected by the hardmask utilized for form the photonic elements). As further illustrated in FIG. 4B, where the thermal oxidation operation 105 and thermal nitridation operation 106 is performed, the annealed SiO₂ layer 205B and the PPL layer 206 is formed on the sidewalls and trench bottoms of the photonic elements 203A, 203B, 203C and.

Continuing with method 300, at operation 311, the hardmask is stripped. In the exemplary embodiment illustrated in FIG. 4B, the annealed SiO₂ layer 205B and the PPL 206 as a stack highly resistant to an etch of Si₃N₄ mask layer 213B (e.g., by phosphoric acid) with an etch of the SiO₂ mask layer 213A (e.g., by 50:1 HF) removing the annealed SiO₂ layer 205B without detriment to the PPL 206. Returning to FIG. 3, method 300 then proceeds to operation 315 with deposition of ILD on the PPL layer and/or bonded transfer of a group III-V semiconductor material on the PPL layer. As illustrated in FIG. 4D, the III-V semiconductor material 225 is bonded to the rib waveguide 227 without the PPL 206 intervening at the silicon top surface 213A. Nonetheless, the PPL 206 remains on sidewall surfaces of the rib waveguide 227, as well at the bottom of the trench 226. As such, both regions remain protected to prevent pitting of the silicon beneath the III-V semiconductor material 225. Method 300 (FIG. 3) then proceeds with completion of the microelectronic device at operation 120, as previously described herein.

In embodiments, a hybrid semiconductor device, such as, but not limited to, the hybrid laser 203C illustrated in FIG. 2A, includes a group III-V semiconductor material having at least one sidewall surface (i.e., edge) offcut from the crystal cleavage planes of the group III-V semiconductor material. As described further herein, removal of a III-V growth substrate with offcut edges can be achieved with little or no crystallographic rim artifact disposed around the transferred group III-V semiconductor material layer(s). As such, the offcut die singulation described herein is not limited to the exemplary PIC embodiments, but rather broadly applicable to any die-level transferred layer process in which a group III-V semiconductor material layer is transferred to a substrate and then thinned at least in part with a chemical etchant

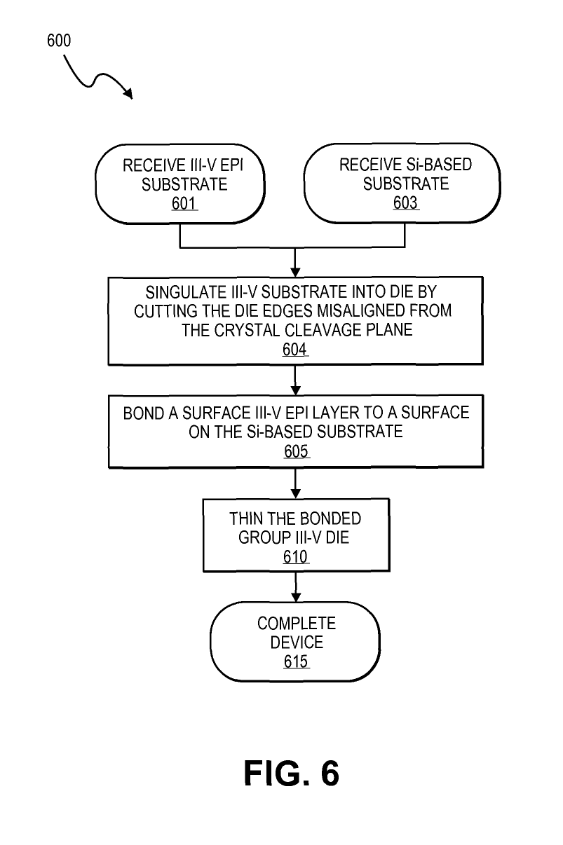

FIG. 6 is a flow diagram illustrating a method 600 for forming a hybrid semiconductor device including an offcut group III-V semiconductor layer disposed on a silicon-based substrate, in accordance with an embodiment. The method 600 begins with receipt of a III-V epitaxial substrate at operation 601. Generally, the III-V epitaxial substrate includes a growth substrate upon which are one or more active epitaxial III-V material layers that are to be bonded and transferred to a silicon-based substrate received at operation 603. In the exemplary embodiment, the III-V epitaxial growth substrate is crystalline InP. In other embodiments, the III-V epitaxial growth substrate is GaAs or GaN. Generally, the active epitaxial stack may include any number of binary, ternary, or quaternary alloys of In, Al, Ga, As, and P, either doped or undoped. In the exemplary embodiment the active epitaxial III-V material layers include at least one n-type InP layer and at least one p-type InGaAs layer and the silicon-based substrate includes a silicon-on-insulator substrate with photonic elements in a silicon device layer (e.g., layer 203 of a PIC as illustrated in FIG. 2A).

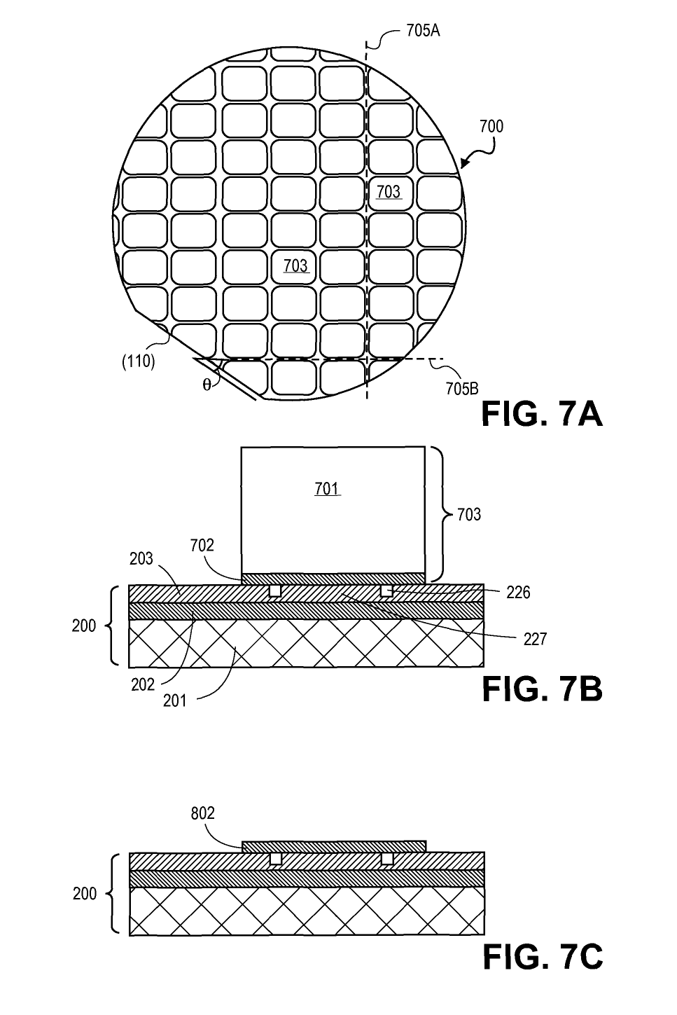

At operation 604, the III-V epitaxial substrate is singulated into die by cutting the die edges misaligned from the crystal cleavage plane. FIG. 7A is a plan view of an exemplary group III-V semiconductor substrate 700 (e.g., including a InP growth substrate) singulated into die 703, in accordance with an embodiment. In the illustrative embodiment, the III-V semiconductor substrate has a (100) crystal orientation (i.e., active surface of die 703 is on (100) plane) and the flat is on the (110) plane. For embodiments having a Zinc Blend crystal structure, the cleavage planes are along the {110} family, parallel and orthogonal to the flat such that cleavage would result in square-shaped die. However, in embodiments the singulation is performed by means other than cleaving to form streets 705A, 705B along other than the cleave planes (i.e., other than {110}). In the embodiment illustrated in FIG. 7A, the street 705A is offcut by an angle θ from the (110) plane of approximately 30°. In the exemplary embodiment however, the offcut angle is between only 5-10° off the {110} planes. As illustrated, the streets 705A and 705B are maintained orthogonal such that all opposing edges of the die 703 remain parallel and are offcut so that any offcut angle θ between 1° and 45° may suffice. It should be noted that in the exemplary embodiment, there are no patterned devices on the group III-V semiconductor substrate 700. However, if desired, patterning should be performed with a predetermined wafer orientation that will accommodate the offcut die singulation.

Various techniques may be used to offcut the die as described. In one embodiment of operation 604, InP die are singulated using a laser microjet (LMJ) process, which can cut nearly arbitrary shapes. A LMJ combines laser energy with a water jet and is commercially available from Synova, Inc. of Lausanne, Switzerland. In further LMJ embodiments, corners of the die 703 are rounded (as shown in FIG. 7A) to minimize stress from bonding. In an alternative embodiment of operation 604, conventional dicing is performed with a dicing saw.

Continuing with the method 600, at operation 605 the die with offcut edges is bonded to the silicon-based substrate. Any conventional bonding process known for bonding the chosen materials may be employed. In the exemplary embodiment, a plasma activation is utilized in the bonding process. FIG. 7B is a side view through a cross-section of a hybrid semiconductor device including the die 703 and SOI substrate 200. As shown, the (100) surface of the active epitaxial layer 702 (e.g., InP) is bonded to the silicon device layer 203, and more specifically disposed on the rib waveguide 227 that forms a base of a hybrid laser (e.g., the hybrid laser 203C illustrated in FIG. 2A).

Returning to FIG. 6, at operation 610, the bonded group III-V die is thinned. Any conventional process known for thinning a bonded die applicable to the growth substrate material may be utilized. As shown for the exemplary embodiment in FIG. 7C, an InP growth substrate 701 is removed with a bulk removal process, and then finished with a wet chemical etch that is selective to a stop layer in the active epitaxial stack (e.g., an InGaAs layer). With the offcut edges, the wet chemical etch may proceed with minimal crystallographic etch artifacts and therefore improved planarity. Method 600 (FIG. 6) then proceeds with completion of the microelectronic device at operation 615, following conventional techniques, and/or incorporating one or more embodiments described elsewhere herein.

In embodiments, a semiconductor device including one or more III-V semiconductor materials employs a contact metallization including an alloy of NiGe. NiGe alloy embodiments have been found to form low-resistance contacts to both n-type and p-type group III-V semiconductor materials. Au-based contact metallization may therefore be avoided for CMOS compatibility. Germanides of Ni have been found to have advantages over other germanides, such as PdGe, because Pd is still considered a contaminant in many CMOS processes (though less so than Au), Ni is much less expensive than Pd, and Ni is also easier to pattern than Pd.

In the exemplary embodiment, a silicon-based PIC including a III-V semiconductor material disposed on a silicon substrate (e.g., a transferred layer or a heteroepitaxial layer) employs NiGe in the contact metallization on a device fabricated in the semiconductor material. In one such embodiment, a NiGe contact metallization is utilized on the semiconductor material 225 of the hybrid laser 203C (FIG. 2A). In further embodiments, NiGe is utilized both on a device fabricated in the bonded semiconductor material and on a device fabricated in a silicon device layer of a silicon-based PIC (e.g., on a p-type MOS transistor). While the exemplary embodiments described herein highlight certain synergies, one of ordinary skill will recognize that a NiGe alloy contact having the advantages described herein may be applied in many other contexts. For example, NiGe contacts may be utilized on any device formed on a III-V semiconductor material, regardless of whether that III-V material is a transferred layer.

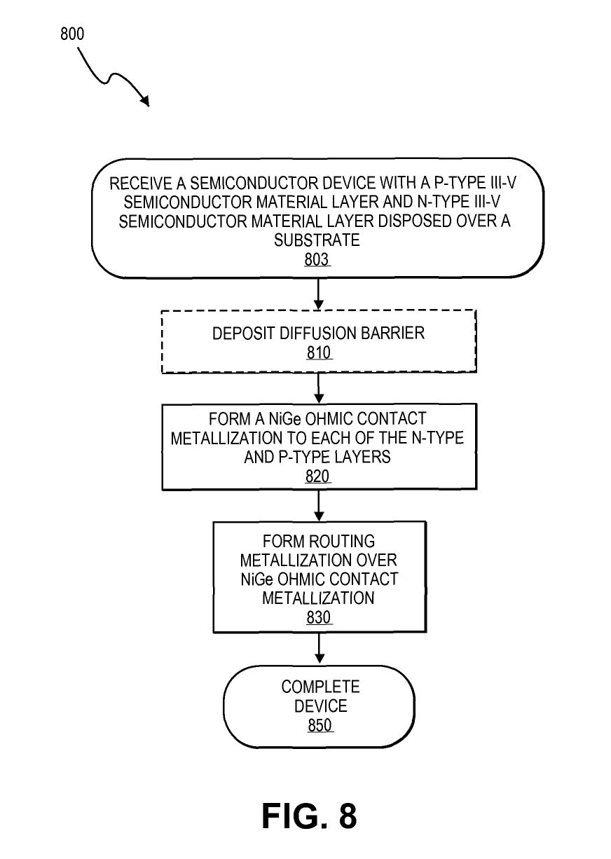

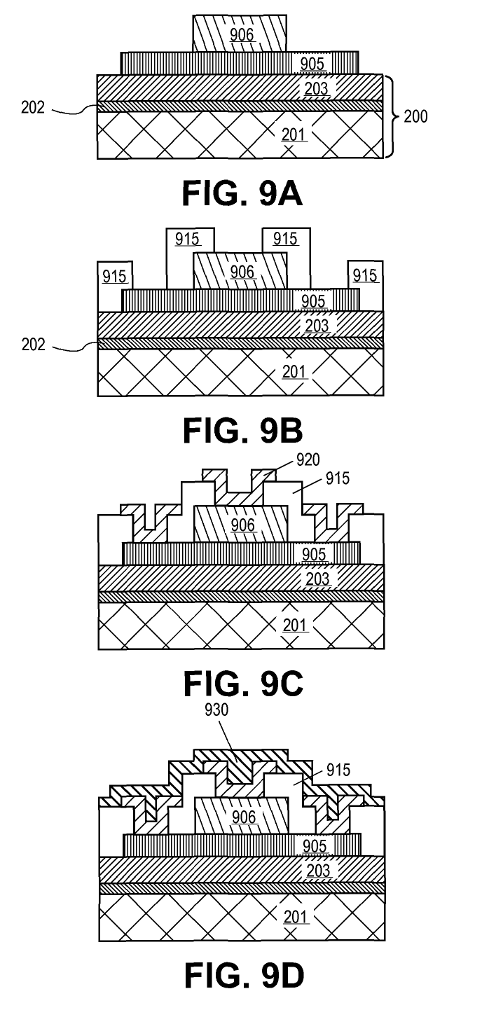

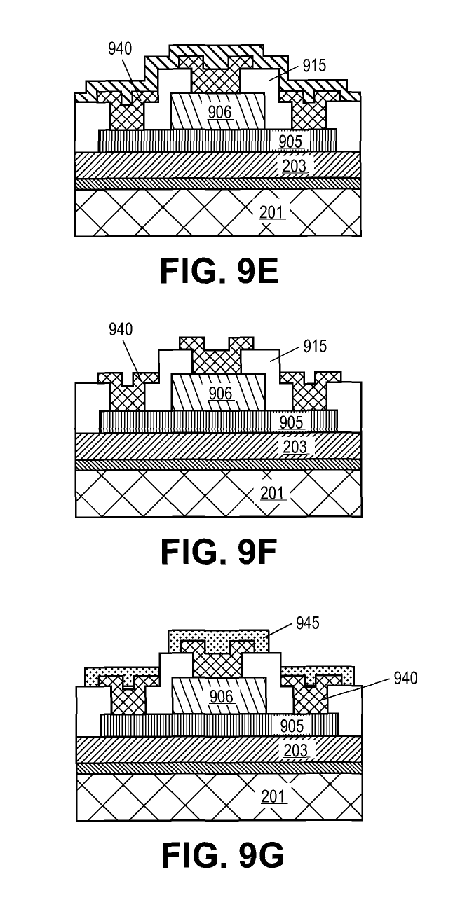

FIG. 8 is a flow diagram illustrating a method 800 for forming contact metallization on a group III-V semiconductor device, in accordance with an embodiment. Method 800 begins at operation 803 with receipt of a semiconductor device with at least one of a p-type III-V semiconductor material layer and an n-type III-V semiconductor material layer disposed over a substrate. The substrate may be either a III-V material (e.g., InP, GaAs, GaN), a group IV material (e.g., Si, Ge, SiGe), or a donor substrate (e.g., sapphire). FIG. 9A is a side view of a cross-section of one exemplary embodiment where the semiconductor device includes both an n-type III-V semiconductor material layer 905, such as, but not limited to, InP, and an p-type III-V semiconductor material layer 906, such as, but not limited to InGaAs, disposed on the silicon SOI substrate 200. As shown, the bonded III-V semiconductor material layers 905, 906 are patterned to expose a p-terminal on a center mesa and two n-terminals on the sides at the lower mesa level. As further shown in FIG. 9B, an ILD 915 is deposited and patterned to form electrically isolated contact openings.

Returning to FIG. 8, in an embodiment method 800 proceeds with operation 810 where a metallic diffusion barrier is deposited, e.g., by physical vapor deposition (PVD), upon one or more of the exposed contact openings to the n-type and p-type layers 905, 906. As denoted by the dashed lines in FIG. 8, operation 810 is optional. In one exemplary embodiment where operation 810 is performed, the diffusion barrier is titanium (Ti). Alternatively, the diffusion barrier may by tungsten (W), or another metal known to serve as a good diffusion barrier. Generally, the diffusion barrier should be thin, between 25 Å and 100 Å with the exemplary embodiment being 50 Å of Ti.

For embodiments employing a diffusion barrier, diffusion of Ni and Ge into the III-V is reduced or prohibited depending on barrier thickness so the III-V material does not alloy with the NiGe alloy contact metal. For this reason, the presence of a diffusion barrier, such as Ti, may enhance reliability by preventing interdiffusion from over the lifetime of the device. Although in the exemplary embodiment illustrated in FIG. 9B, the ILD 915 is opened over both the n-type and p-type III-V material layer 905, 906 so that a diffusion barrier is disposed on both the p-type and n-type contacts, in an alternative embodiment a diffusion barrier is disposed only on the p-type III-V semiconductor material layer 906. Though not bound by theory, it is believed that the n-type contacts benefit from the III-V semiconductor becoming doped with Ge, while the p-contacts are degraded by such doping. Lower contact resistance may be achieved in embodiments where the diffusion barrier is deposited only in the p-type III-V semiconductor material layer 906 (e.g., with ILD 915 patterned to independently open p-type and n-type contacts).

Referring still to FIG. 8, at operation 820 a NiGe ohmic contact metallization is formed to at least one, and preferably both, of the p-type and n-type III-V semiconductor materials. Though different compositions are possible for the NiGe alloy, in the exemplary embodiment the alloy is binary consisting essentially of Ni and Ge. Experiments varying the ratio of Ni to Ge indicated best results are achieved where there is an (atomic) excess of Ni. In the exemplary embodiments, the atomic ratio of Ni:Ge is between 1.25:1 and 5:1.

Many techniques may be utilized to deposit the NiGe alloy, including co-sputtering of separate targets or sputtering of a NiGe alloy target having a composition that will provide the desired alloy composition for the contact metallization. In the exemplary embodiment however, separate layers of Ge and Ni are deposited and then annealed into an alloy. As shown in FIG. 9C, a Ge layer 920 is first deposited (e.g., by PVD) over the p-type and n-type III-V semiconductor layers 905 and 906 (directly on one or both where a diffusion barrier is not employed). The Ge layer 920 is patterned by conventional etching techniques (e.g., plasma etch) to expose ILD 915 between the separate contacts. Subsequently, as shown in FIG. 9D, a Ni layer 930 is deposited (e.g., by PVD) on the Ge layer 920 and the exposed ILD 915. The Ni layer 930 is deposited to a thickness relative to the thickness of Ge layer 920 corresponding to the desired alloy composition. Assuming bulk density for both the Ge and Ni layers 920, 930, to achieve an atomic ratio of 1:1, the Ni layer 930 should be deposited to approximately half the thickness of the Ge layer 920. To fall within the exemplary range of atomic ratio (1.25:1-5:1 Ni:Ge), the thickness of the Ni layer 930 relative to the thickness Ge layer 920 should be proportionally increased.

An anneal is performed to alloy the Ge and Ni layers 920, 930 into a NiGe alloy (germanide) layer 940, as illustrated in FIG. 9E. Generally, any conventional contact anneal process may be employed, such as, but not limited to furnace anneal, rapid thermal anneal (RTA), flash anneal, or laser anneal (melt or sub-melt). In the exemplary embodiment, RTA is utilized at a temperature of between 250° C. and 400° C. for a duration of 30 seconds. While the specific contact resistance (R_{c}) for an n-type contact was found to be under 1×10⁻⁵ Ω-cm over this entire anneal temperature range, for a p-type contact to have an Rc better than 2×10⁻⁵ Ω-cm an anneal should be over 300° C., and preferably at least 350° C. Following anneal, excess Ni on the surface of the substrate disposed over the ILD 915 or unreacted Ni disposed over the NiGe contact metallization is removed, for example by wet etch, as illustrated by FIG. 9G.

Returning to FIG. 8, the method 800 proceeds to operation 830 with the contact metallization completed with deposition and patterning of routing metallization (e.g., metal layer 945 in FIG. 9G) by any means known in the art. As should be apparent to one of skill, the nickel germanide contact metallization illustrated in FIGS. 9A-9G is a self aligned germanide contact metallization having many of the same benefits as a self-aligned silicide (“salicide”) contact metallization typical in MOS devices. Method 800 then proceeds with completion of the microelectronic device at operation 850, following conventional practices.

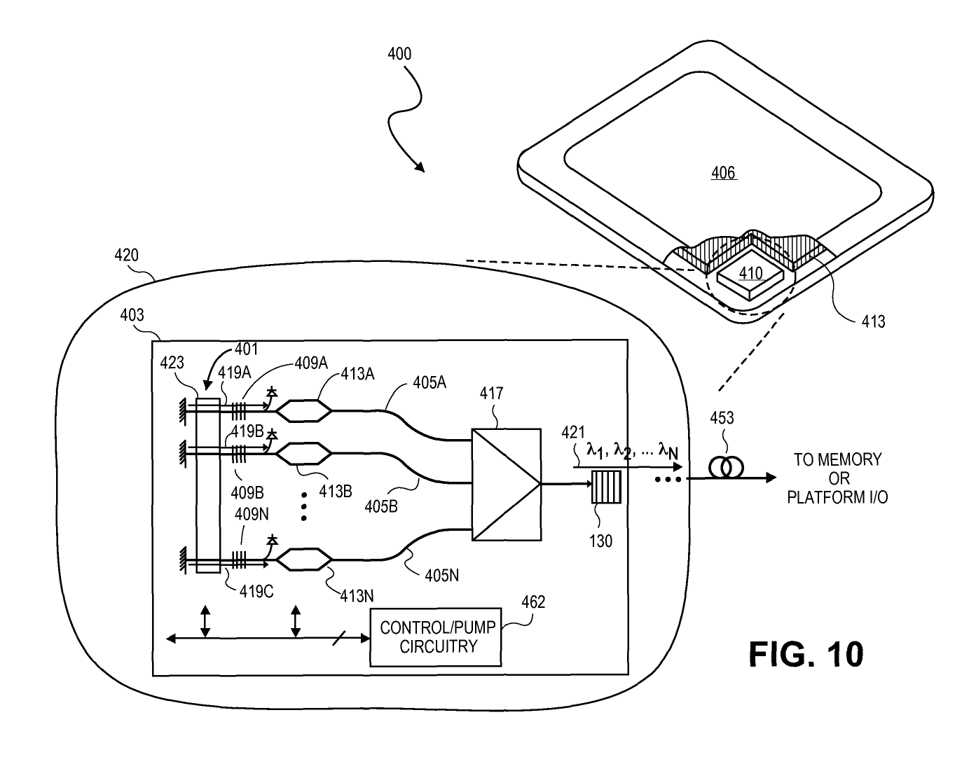

While the PPLs, silicon/III-V hybrid photonic devices, and contact metallization techniques and structures described herein may be utilized individually or in combination within many system-level applications, FIG. 10 is a schematic diagram of a mobile computing platform including an optical transmitter in accordance with embodiments of the present invention.

The mobile computing platform 400 may be any portable device configured for each of electronic data display, electronic data processing, and wireless electronic data transmission. For example, mobile computing platform 400 may be any of a laptop, a netbook, a notebook, an ultrabook, a tablet, a smart phone, etc. and includes a display screen 406, which may be a touchscreen (e.g., capacitive, resistive, etc.) the optical transmitter 410, and a battery 413.

The optical transmitter 410 is further illustrated in the expanded functional block view 420 illustrating an array of electrically pumped lasers 401 controlled by circuitry 462 coupled to a passive semiconductor layer over, on, or in, substrate 403. The semiconductor substrate 403 further includes a plurality of optical waveguides 405A-405N over which a bar of III-V semiconductor gain medium material 423 with offcut edges is bonded to create, along with the reflectors 409A-409N, an array of hybrid lasers that include NiGe contact metallization. During operation, a plurality of optical beams 419A-419N are generated within the plurality of optical waveguides 405A-405N, respectively, which may be passivated with a PPL, as described herein. The plurality of optical beams 419A-419N are modulated by modulators 413A-413N and then selected wavelengths of the plurality of optical beams 419A-419N are then combined in with optical add-drop multiplexer 417 to output a single optical beam 421 through a grating coupler 130, which is then to be optically coupled into an optical wire 453. The optical wire 453 is further coupled to a downstream optical receiver external to the mobile computing platform 400 (i.e., coupled through the platform optical I/O terminal) or is further coupled to a downstream optical receiver internal to the mobile computing platform 400 (i.e., a memory module).

In one embodiment, the optical wire 453 is capable of transmitting data at the multiple wavelengths included in the optical beam 421 at speeds of at least 25 Gb/s and potentially more than 1 Tb/s. In one example, the plurality of optical waveguides 405A-405N are in a single silicon layer for an entire bus of optical data occupying a PIC chip of less than 4 mm on a side.

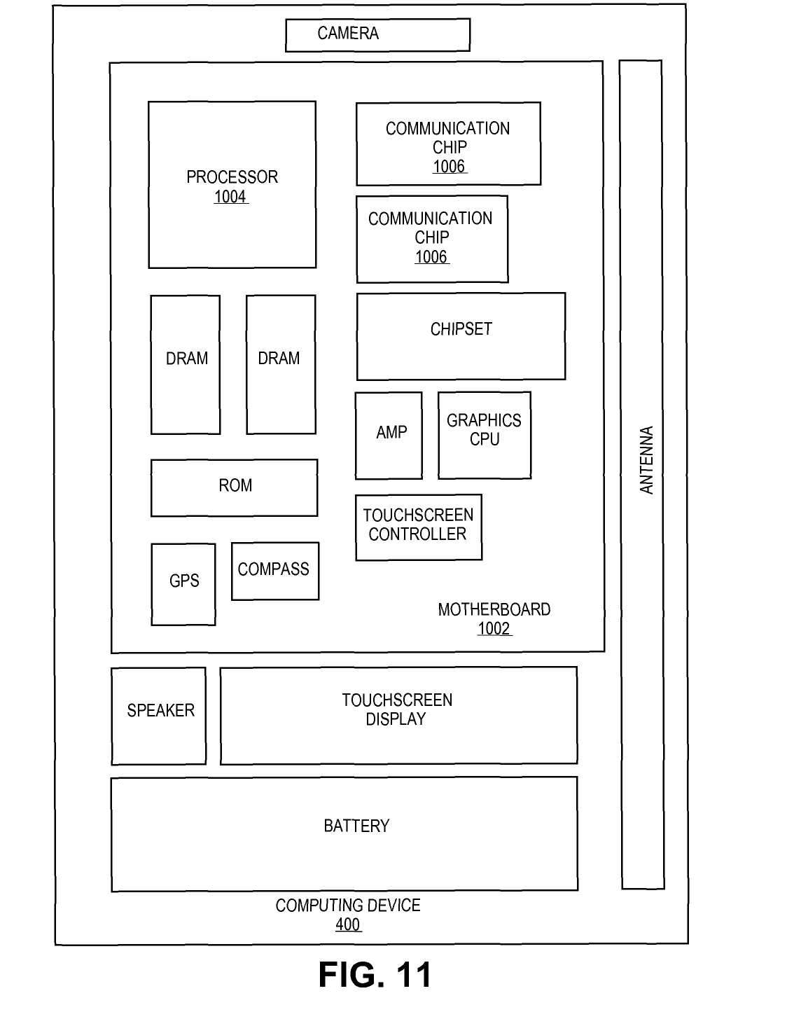

FIG. 11 is a functional block diagram of the mobile computing platform 400 in accordance with one embodiment of the invention. The mobile computing platform 400 includes a board 1002. The board 1002 may include a number of components, including but not limited to a processor 1004 and at least one communication chip 1006. The processor 1004 is physically and electrically coupled to the board 1002. In some implementations the at least one communication chip 1006 is also physically and electrically coupled to the board 1002. In further implementations, the communication chip 1006 is part of the processor 1004. Depending on its applications, mobile computing platform 400 may include other components that may or may not be physically and electrically coupled to the board 1002. These other components include, but are not limited to, volatile memory (e.g., DRAM), non-volatile memory (e.g., ROM), flash memory, a graphics processor, a digital signal processor, a crypto processor, a chipset, an antenna, touchscreen display, touchscreen controller, battery, audio codec, video codec, power amplifier, global positioning system (GPS) device, compass, accelerometer, gyroscope, speaker, camera, and mass storage device (such as hard disk drive, solid state drive (SSD), compact disk (CD), digital versatile disk (DVD), and so forth).

At least one of the communication chips 1006 enables wireless communications for the transfer of data to and from the mobile computing platform 400. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The mobile computing platform 400 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 includes an integrated circuit die packaged within the processor 1004. The term “processor” may refer to any device or portion of a device that processes electronic data from registers and/or memory to transform that electronic data into other electronic data that may be stored in registers and/or memory. Either of the communications chip 1006 may entail the optical transmitter 100, substantially as described elsewhere herein.

It is to be understood that the above description is illustrative, and not restrictive. For example, while flow diagrams in the figures show a particular order of operations performed by certain embodiments of the invention, it should be understood that such order may not be required (e.g., alternative embodiments may perform the operations in a different order, combine certain operations, overlap certain operations, etc.). Furthermore, many other embodiments will be apparent to those of skill in the art upon reading and understanding the above description. Although the present invention has been described with reference to specific exemplary embodiments, it will be recognized that the invention is not limited to the embodiments described, but can be practiced with modification and alteration within the spirit and scope of the appended claims. The scope of the invention should, therefore, be determined with reference to the appended claims, along with the full scope of equivalents to which such claims are entitled.

1. A photonic integrated circuit (PIC), comprising:
photonic element comprising silicon disposed on a substrate;
a photonic passivation layer (PPL) comprising a nitrogen-doped silicon oxide having a thickness of less than 100 Å disposed on the photonic element; and
an interlayer dielectric (ILD) disposed on the PPL.

2. The PIC of claim 1, wherein the PPL has a thickness between 5 Å and 15 Å.

3. The PIC of claim 1, wherein the PPL has a concentration of nitrogen atoms between 10¹² and 10¹⁶ atoms/cm³.

4. The PIC of claim 1, wherein the photonic element consists essentially of silicon and is selected from the group consisting of: a grating, a waveguide, and a multimode interference (MMI) coupler.

5. The PIC of claim 1, further comprising a group III-V semiconductor material bonded to the PPL, and wherein the ILD is disposed over the bonded group III-V semiconductor material.

6. A method of fabricating a photonic integrated circuit (PIC), the method comprising:
forming a photonic element comprising silicon on a substrate;
forming a silicon dioxide layer on the photonic element; and
forming a photonic passivation layer (PPL) by nitriding at least a portion of the silicon dioxide layer.

7. The method of claim 6, further comprising: removing a portion of the silicon dioxide layer with a wet chemical etchant of silicon dioxide after forming the PPL.

8. The method of claim 6, wherein forming the silicon dioxide layer further comprises at least one of a thermal oxidation or radical oxidation of the photonic element, and wherein nitriding the silicon dioxide layer further comprises diffusing nitrogen through at least a portion of the silicon dioxide layer.

9. The method of claim 8, wherein the photonic element comprises a waveguide consisting essentially of silicon and wherein the method further comprises forming a hybrid laser by bonding a group III-V semiconductor material on the PPL disposed on the waveguide.

10. The method of claim 6, wherein the PPL is selectively formed over first surfaces of the photonic element while second surfaces remain free of the PPL.

11. A photonic integrated circuit (PIC), comprising:
a waveguide disposed on a silicon substrate; and
a hybrid semiconductor device including a crystalline group III-V semiconductor material bonded to the waveguide, wherein the group III-V semiconductor material has at least one sidewall surface offcut from the crystal cleavage planes of the group III-V semiconductor material.

12. The PIC of claim 11, wherein the crystalline group III-V semiconductor material has a (100) surface bonded to the waveguide, and wherein the sidewall surfaces are offcut from the {110} planes.

13. The PIC of claim 11, wherein the sidewall surface is offcut from the crystal cleavage planes by 5°-10°.

14. The PIC of claim 11, wherein the group III-V semiconductor material comprises an epitaxial stack including a plurality of group III-V semiconductor layers and wherein opposing sidewalls of the group III-V semiconductor material are all offcut by substantially the same amount to remain substantially parallel.

15. The PIC of claim 11, wherein the hybrid semiconductor device is a laser and wherein the waveguide comprises crystalline silicon.

16. A method of fabricating a hybrid semiconductor device, the method comprising:
singulating a crystalline group III-V semiconductor substrate into die by cutting the die edges misaligned from the crystal cleavage planes of the group III-V semiconductor material;
bonding a surface of a group III-V semiconductor material layer disposed on the group III-V semiconductor die to surface on a silicon semiconductor substrate; and
thinning the bonded group III-V semiconductor die by removing a bulk of the group III-V semiconductor substrate material from the group III-V semiconductor material layer.

17. The method of claim 16, wherein removing the group III-V semiconductor substrate further comprises a chemical wet etching process.

18. The method of claim 16, wherein the singulating comprises at least one of a laser singulation process or a saw dicing process.

19. The method of claim 18, wherein the laser-based dicing process further comprises offcutting the die edges with a laser micro jet.

20. The method of claim 16, wherein bonding the surface of the group III-V semiconductor material layer further comprises bonding a (100) surface of a epitaxial layer, and wherein the surface on the silicon substrate is a surface of a waveguide comprising at least one of silicon and silicon dioxide.

21. A semiconductor device, comprising:
a p-type group III-V semiconductor material layer disposed over a substrate;
an n-type group III-V semiconductor material layer disposed over the substrate; and
a contact metallization disposed over both the p-type and n-type group III-V semiconductor material layers, wherein the contact metallization comprises a NiGe alloy.

22. The device of claim 21, wherein contact metallization consists essentially of a the NiGe alloy disposed directly on the n-type group III-V semiconductor material layer, and the NiGe alloy disposed over the p-type group III-V semiconductor material layer with a diffusion barrier disposed there between.

23. The device of claim 21, wherein the substrate comprises silicon and wherein the p-type group III-V semiconductor material layer comprises Ga and As and wherein the n-type group III-V semiconductor material layer comprises In and P.

24. The device of claim 23, wherein the p-type group III-V semiconductor material layer consists essentially of InGaAs and wherein the n-type group III-V semiconductor material layer consists essentially of InP.

25. The device of claim 21, wherein the atomic ratio of Ni to Ge in the NiGe alloy is between 1.5:1 and 5:1.

26.-31. (canceled)
